(19) United States
(12) Patent Application Publication
(10) Pub. No.: US 2025/0329372 A1
(43) Pub. Date: Oct. 23, 2025

(54) APPARATUSES AND METHODS FOR ON-DEVICE TELEMETRY LOGGING

(71) Applicant: Micron Technology, Inc., Boise, ID (US)

(72) Inventors: Evan C. Pearson, Boise, ID (US); Dale H. Hiscock, Boise, ID (US); Owen Straub, Boise, ID (US); Anthony M. Geidl, Boise, ID (US); John R. Lynch, Boise, ID (US)

(73) Assignee: Micron Technology, Inc., Boise, ID (US)

(21) Appl. No.: 19/089,493

(22) Filed: Mar. 25, 2025

Related U.S. Application Data
(60) Provisional application No. 63/637,511, filed on Apr. 23, 2024.

(51) Int. Cl. G11C 11/408

(52) U.S. Cl. CPC G11C 11/4087

(57) ABSTRACT

A memory device logs telemetry information using a resistive element array. A telemetry logging circuit changes a resistance of one or more resistive elements in the array responsive to one or more commands, addresses, mode signals, or combinations thereof. The change to the resistance may be cumulative with other changes. For example if the resistive element is an antifuse, the resistance may decrease each time the information is logged. In some example embodiments, the memory may read out a resistance of one or more of the resistive elements to determine a telemetry value, which may be written to storage such as a mode register or SPD.

### CROSS REFERENCE TO RELATED APPLICATION(S)

This application claims the benefit under 35 U.S.C. § 119 of the earlier filing date of U.S. Provisional Application Ser. No. 63/637,511 filed Apr. 23, 2024 the entire contents of which is hereby incorporated by reference in its entirety for any purpose.

### BACKGROUND

This disclosure relates generally to semiconductor devices, and more specifically to semiconductor memory devices. In particular, the disclosure relates to volatile memory, such as dynamic random access memory (DRAM). Information may be stored on individual memory cells of the memory as a physical signal (e.g., a charge on a capacitive element). During an access operation, an access command may be received along with address information which specifies which memory cells should be accessed. Some devices, such as memory modules, may package multiple memory devices together. A controller may operate the memory device(s) by issuing the commands and addresses.

It may be useful to gather telemetry information such as information about the types of commands received by the memory, the addresses received by the memory or other information. However it may be logistically difficult to gather such information from the controller. There may be a need for on-die telemetry logging.

### BRIEF DESCRIPTION OF THE DRAWINGS

FIG. 1 is a block diagram of a memory system according to some embodiments of the present disclosure.

FIG. 2 is a block diagram of a semiconductor device according to some embodiments of the disclosure.

FIG. 3 is a block diagram of a telemetry logging logic according to some embodiments of the present disclosure.

FIG. 4 is a flow chart of a method of logging telemetry information according to some embodiments of the present disclosure.

FIG. 5 is a flow chart of a method of reading telemetry information stored on a memory device according to some embodiments of the present disclosure.

### DETAILED DESCRIPTION

The following description of certain embodiments is merely exemplary in nature and is in no way intended to limit the scope of the disclosure or its applications or uses. In the following detailed description of embodiments of the present systems (e.g., memory systems), apparatuses (e.g., memory devices, circuits, semiconductor devices), methods, or combinations thereof, reference is made to the accompanying drawings which form a part hereof, and which are shown by way of illustration specific embodiments in which the described systems, apparatuses, and methods may be practiced. These embodiments are described in sufficient detail to enable those skilled in the art to practice presently disclosed systems, apparatuses, and methods, and it is to be understood that other embodiments may be utilized and that structural and logical changes may be made without departing from the spirit and scope of the disclosure. Moreover, for the purpose of clarity, detailed descriptions of certain features will not be discussed when they would be apparent to those with skill in the art so as not to obscure the description of embodiments of the disclosure. The following detailed description is therefore not to be taken in a limiting sense, and the scope of the disclosure is defined only by the appended claims.

Memory devices store information in memory arrays. The memory array includes memory cells, organized at the intersection of word lines (rows) and bit lines (columns). Each memory cell may store a bit of information. During an access operation, a row address may be used to specify a word line and a column address may be used to specify one or more bit lines. The information in the memory cells at the intersection of the specified word line and bit lines may be accessed.

There may be a variety of applications where it is useful to track telemetry metrics about how the memory is operated. The telemetry metrics may be useful for a variety of applications, such as for diagnostics, for guiding future design of memory devices, for feedback about how outside parties use the memory, or combinations thereof. While a controller may track telemetry information, using the controller for this purpose may be less desirable in some circumstances. For example, a company that manufactures memory devices may have difficulty retrieving such information if a different company manufactures the controller. There may thus be a need for on-device telemetry logging.

The present disclosure is drawn to apparatuses, systems, and methods for on-device telemetry logging. According to at least some embodiments of the present disclosure, a memory device includes an array of resistive elements, such as antifuses. When a voltage is applied to the resistive element, its resistance may change. The change may be less than when the resistive element is ‘blown’. For example, the voltage may be much less than a voltage required to blow the resistive element, and the change in resistance may be relatively small. The change to the resistance may be permanent, and each time the voltage is applied the change may be cumulative with previous changes to the resistance. In this manner, the resistance of the resistive element may indicate the number of times that the voltage was applied, and the resistance of the resistive element may thus act as a form of non-volatile storage.

The array of resistive elements includes different sets of elements of one or more resistive elements apiece, that can act as storage for different pieces of telemetry. For example, when a read command is received, a telemetry logging circuit may apply a voltage to a resistive element used to store read command logging. This may change the resistance of that element. Accordingly, the resistance of that element will encode information about the number of read commands. Other information may be stored in a similar manner. For example, different sets of antifuses may store information about different commands, about different addresses which are activated, about different modes of operation of the memory device, or combinations thereof.

In some example embodiments, the telemetry information may be read directly off the device by having an external device check the resistances in the array of resistive elements. In some embodiments, a circuit of the memory device may be used to read the telemetry information by checking resistances. In some embodiments, memory device may read out the telemetry information and then write that telemetry information, information derived from that telemetry information, or combinations thereof to a storage array of the memory, such as a mode register, to a storage array of the module, such as a serial presence detect (SPD) chip of the module, or combinations thereof.

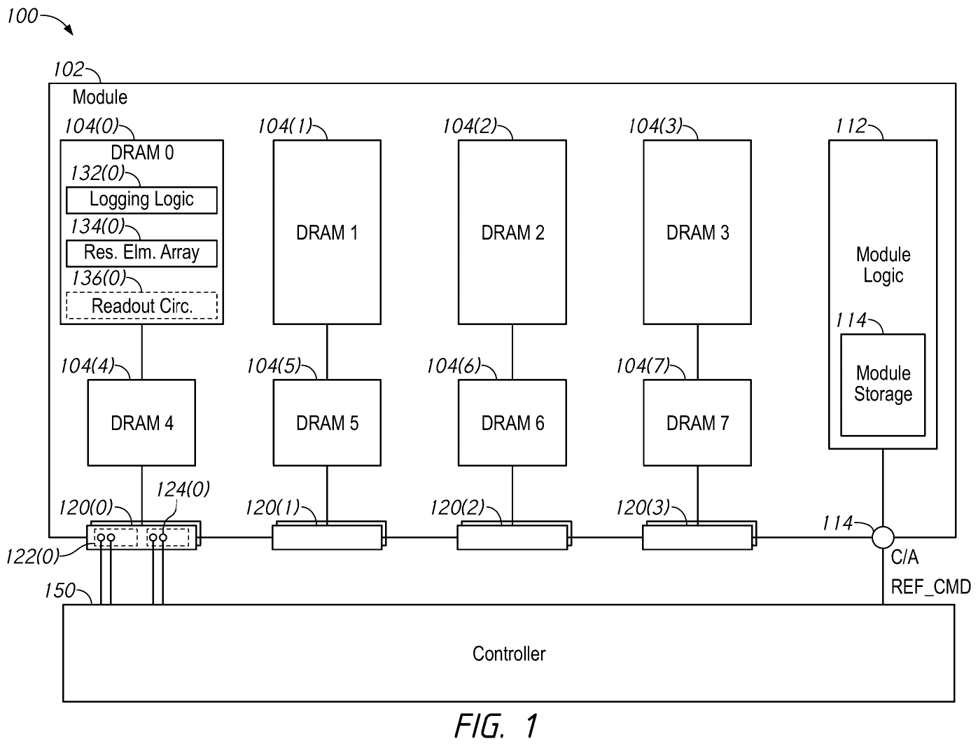

FIG. 1 is a block diagram of a memory system according to some embodiments of the present disclosure. The memory system 100 includes a memory module 102 and a controller 150. The controller 150 operates the memory module 102. The module 102 includes one or more memory devices 104. The memory devices 104 are used to store information such as data. In some embodiments, some memory devices 104 may be set aside for other purposes, such as storing error correction information. A module logic circuit 112 receives signals such as commands and addresses over a command/address C/A bus from the controller 150 through a C/A terminal 114 and distributes those commands and addresses to the memory devices 104 over internal command and address buses (not shown). Data is communicated between the controller 150 and the module 102 along data buses which couple to data terminals (DQ) terminals 124 of the module 102. The data terminals 124 are organized into pseudo-channels 122 and channels 120. Each channel 120 is a set of data terminals 124 associated with a memory device 104. A similar set of channels 128 couple the error correction devices 110 to the controller 150. FIG. 1 shows eight memory devices 104(0) to 104(7) on the module 102, however more or fewer memory devices 104 may be used in other example embodiments.

The memory devices 104 are coupled to the controller through respective channels 120. In some embodiments, there may be a channel 120 for each memory device 124. In some embodiments, some memory devices 104 may share a channel 120. Each channel 120 includes one or more pseudo-channels 122, each of which includes one or more data terminals 124. The pseudo-channels 122 may be operated independently of each other. In this embodiment, each channel 120 includes two pseudo-channels 122, each of which includes two data terminals 124. Since the memory devices 104 and channels 120 may generally be similar to each other, only a single device 104(0) and its associate channel 120(0) are described in detail herein. Similarly, only internal components of a single data device 104(0) are shown and described. However, each of the data devices 104 may have similar components. Other numbers of pseudo-channels 122 per channel and other numbers of data terminals 124 per pseudo-channels may be used in other example embodiments.

In order to simplify the layout of the figure, an arrangement of two rows of four data devices 104 is shown, and their associated channels 120 are shown as stacked boxes. However the representation of FIG. 1 does not necessarily represent the layout of a physical device. For example, a single row of 8 data devices 104. Similarly, various buses and signal lines have been simplified down to a single line for clarity on the drawing, however, multiple physical signal lines may be represented by a single line in the drawing.

During an example write operation, the controller 150 provides a write command and addresses (e.g., a row address, column address, bank address, or combinations thereof as explained in more detail herein) over the C/A terminal 114 to the module 102. The module logic 112 distributes the command and address to the data memory devices 104(0) to 104(7) and ECC devices 110(0) and 110(1). The controller 150 also provides data to be written along the various DQ channels 120. Since the pseudo-channels 122 may be operated independently, we will consider a single pseudo-channel 122 and its two DQ terminals 124. Each data terminal 124 receives a serial burst of bits, which together represent a codeword of data. For example, the memory device 104 may receive a burst of 16 serial bits along each of four DQ terminals for a total of 64 bits. The received data is written to the memory array of the data devices 104.

During an example read operation, the controller 150 provides a read command and addresses along the C/A terminal 114. The module logic 112 distributes these to the memory devices 104 and data is read out from the locations specified by the addresses in the data devices 104 to the data terminals 124 in the active pseudo-channel 122 of the channel 120.

The memory devices may also operate in different modes. The memory device 104 may enter various modes based on commands or other signals received from the controller 150, based on internal logic, or combinations thereof. Various mode signals within the memory device 104 may indicate which mode the memory is in. For example, the memory device 104 may enter into a self-refresh mode when it is in a standby state. During the self-refresh mode the memory device 104 may generate an internal self-refresh signal in order to periodically refresh data stored on the device 104. The internal self-refresh signal may be used as a mode signal to indicate when the memory device 104 is in a self-refresh mode.

Each memory device 104 includes a telemetry logging circuit 132 and an array of resistive elements 134. The array of resistive elements 134 includes one or more resistive elements which can have their resistance permanently changed. For example, the array 134 may include fuses, antifuses, or combinations thereof. The resistive elements may start at a first resistive state, and if a voltage above a threshold voltage is applied, become ‘blown’ and switch to an opposite resistive state. For example, a fuse may begin as conductive, idealized as having no resistance, and after being blown may become a circuit break idealized as having infinite resistance. An antifuse may begin as a circuit break idealized as having infinite resistance and after being blown may be conductive idealized as having no resistance. If a voltage less than the threshold voltage is applied, the resistive element may still permanently change its resistance, but to a small degree which is the not the full change represented by being blown. For example, when the telemetry logging circuit 132 applies a voltage to an antifuse, the resistance of the antifuse will decrease slightly, but not go to zero.

The telemetry logging circuit 132 alters the resistance of one or more of the resistive elements in the array 134 based on received commands, addresses, modes of the memory device, or combinations thereof. The telemetry logging circuit 132 may alter the resistance based on a number of times a signal is received, a number of times a signal is generated, an amount of time a signal is active or inactive for (e.g., as measured in clock cycles), or combinations thereof. In some embodiments, the array 134 may include one or more sets of resistive elements, and each set may be used to log a piece of telemetry information. For example a first set could log how many read commands are received, a second set could log how many addresses within a certain range of address values are received, and so forth.

The telemetry logging circuit 132 determines if there is telemetry to be logged based on the commands, addresses, mode signals, or combinations thereof, and if so applies a voltage to the corresponding set(s) of resistive elements. The applied voltage may cause a permanent change in the resistance of the resistive element(s) that is less than the change when the element(s) are blown. For example, if the resistive element is an antifuse, then the voltage may cause the antifuse to have less resistance. The telemetry logging circuit 132 may cause changes which are cumulative. For example, if the voltage is applied to an antifuse a first time its resistance may decrease from an initial level to a first level, and when the voltage is applied to the antifuse a next time the resistance may decrease from the first level to a second level.

In some embodiments, the memory 104 may include an optional readout circuit 136. The readout circuit 136 may read the resistance values of one or more of the resistive elements in the array 134. The readout circuit 136 may output one or more values which can be stored in the memory device 104, on the module 102, or combinations thereof. For example, the values based on the resistances may be written to a mode register of the memory device 104, a module storage circuit 114 such as an SPD, or combinations thereof. In some embodiments, the value may directly reflect the measured resistance. In some embodiments, the value may be based on the measured resistance, for example the value may reflect which range bin the measured resistance is in. In some embodiments, different telemetry information may be combined into the value. For example, the readout circuit 136 may read a first set of resistive elements which indicate a number of read commands, read a second set of resistive elements which indicate a number of write commands, and then output a value which is based on a ratio of the number of read and write commands.

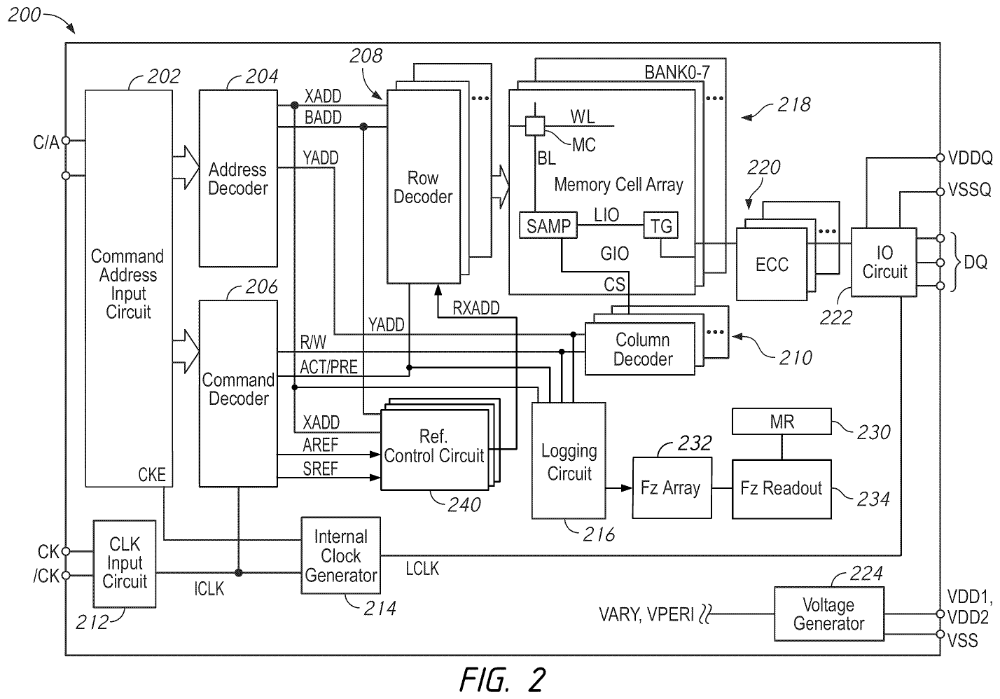

FIG. 2 is a block diagram of a semiconductor device according to some embodiments of the disclosure. The semiconductor device 200 may be a semiconductor memory device, such as a DRAM device integrated on a single semiconductor chip. For example, the device 100 may implement one of the devices 104 of the module 102 of FIG. 1. In some embodiments, the memory device 200 may be a stand alone memory device which is not packaged together onto a module.

The semiconductor device 200 includes a memory array 218. The memory array 218 may be organized into one or more memory banks. In the embodiment of FIG. 2, the memory array 218 is shown as including eight memory banks BANK0-BANK7. More or fewer banks may be included in the memory array 218 of other embodiments.

Each memory bank includes a plurality of word lines WL, a plurality of bit lines BL, and a plurality of memory cells MC arranged at intersections of the plurality of word lines WL and the plurality of bit lines BL. The selection of the word line WL is performed by a row decoder 208 based on a row address XADD and the selection of the bit lines BL is performed by a column decoder 210 based on a column address YADD. In the embodiment of FIG. 2, the row decoder 208 includes a respective row decoder for each memory bank and the column decoder 210 includes a respective column decoder for each memory bank. The address decoder 204 may use the bank address BADD to determine which column decoder 210 and row decoder 208 to use, in turn determining which bank is accessed.

The bit lines BL are coupled to a respective sense amplifier (SAMP). Read data from the bit line BL is amplified by the sense amplifier SAMP, and transferred to an ECC circuit 220 over local data lines (LIO), transfer gate (TG), and global data lines (GIO). Conversely, write data outputted from the ECC circuit 220 is transferred to the sense amplifier SAMP over the complementary main data lines GIO, the transfer gate TG, and the complementary local data lines LIO, and written in the memory cell MC coupled to the bit line BL.

The semiconductor device 200 may employ a plurality of external terminals, such as solder pads, that include command and address (C/A) terminals coupled to a command and address bus to receive commands and addresses, clock terminals to receive clocks CK and/CK, data terminals DQ coupled to a data bus to provide data, and power supply terminals to receive power supply potentials VDD, VSS, VDDQ, and VSSQ. The external terminals may couple directly to the controller (e.g., 150 of FIG. 1), may couple to various buses/connectors of the module (e.g., 102 of FIG. 1), or combinations thereof.

The clock terminals are supplied with external clocks CK and/CK that are provided to an input circuit 212. The external clocks may be complementary. The input circuit 212 generates an internal clock ICLK based on the CK and/CK clocks. The ICLK clock is provided to the command decoder 206 and to an internal clock generator 214. The internal clock generator 214 provides various internal clocks LCLK based on the ICLK clock. The LCLK clocks may be used for timing operation of various internal circuits. The internal data clocks LCLK are provided to the input/output circuit 222 to time operation of circuits included in the input/output circuit 222, for example, to data receivers to time the receipt of write data. The input/output circuit 222 may include one or more interface connections, each of which may be couplable to one of the DQ pads. For example, the solder pads may act as external connections to the device 200.

The C/A terminals may be supplied with memory addresses. The memory addresses supplied to the C/A terminals are transferred, via a command/address input circuit 202, to an address decoder 204. The address decoder 204 decodes the address into a bank address, row address, and column address. The bank address BADD selects the row decoder 108 and column decoder 110 and thus selects the bank. The address decoder 204 supplies a decoded row address XADD to the row decoder 208 selected by BADD and supplies a decoded column address YADD to the column decoder 210 selected by BADD. The decoded row address XADD may be used to determine which row is opened or activated, coupling the memory cells along the activated word line to the intersecting bit lines. The column decoder 110 provides a column select signal CS based on the column address YADD. The CS signal selects which bit lines are coupled to local input/output lines, allowing those bit lines to be accessed.

The C/A terminals may be supplied with commands. Examples of commands include timing commands for controlling the timing of various operations, access commands for accessing the memory, such as read commands for performing read operations and write commands for performing write operations, refresh commands such as all-bank refresh and partial bank refresh, as well as other commands and operations. Some commands, such as self-refresh entry and exit commands, may change a mode of the memory device 200. The access commands may be associated with one or more row address XADD, column address YADD, and bank address BADD to indicate the memory cell(s) to be accessed.

The commands may be provided as internal command signals to a command decoder 206 via the command/address input circuit 202. The command decoder 206 includes circuits to decode the internal command signals to generate various internal signals and commands for performing operations. For example, the command decoder 206 may provide signals such as a read signal R, write signal W, row activation signal ACT, row pre-charge signal PRE or combinations thereof. The command decoder 206 may also perform other functions, such as providing a refresh signal responsive to a refresh command.

In an example write operation, the device 200 writes data received at the DQ terminals to the memory cells specified by a received bank, row and column address. As part of the write operation, the command decoder 206 receives a write command and activation command and provides internal signals such as W and ACT/PRE. The write data is received by the IO circuit 222 and provided to the RWAMP circuit 220. The row decoder 208 selected by BADD activates the row selected by XADD responsive to the internal activation signal ACT. The column decoder 210 selected by BADD couples the bit lines selected by YADD to the LIO and GIO lines to the RWAMP circuit 220. The sense amplifiers drive the voltages on the coupled bit lines to write the write data to the memory cells at the intersection with the active word line. The row is pre-charged responsive to the pre-charge signal PRE.

In an example read operation, the device 200 reads data from the memory cells specified by a received bank, row, and column address and provides that read data to the DQ terminals. As part of the read operation, the command decoder 206 receives a read command and an activation command and provides internal signals such as a read signal R, and ACT/PRE. The row decoder 208 selected by BADD activates the row selected by XADD responsive to the internal row activation signal ACT. The column decoder 210 selected by BADD couples the bit lines selected by YADD to the LIO and GIO lines to the RWAMP circuit 220. The RWAMP circuit 220 provides the read data to the IO circuit 222 and the IO circuit 222 provides the read data to the DQ terminals. The row is pre-charged responsive to PRE.

The device 200 includes a refresh control circuit 240. The refresh control circuit 240 provides one or more refresh addresses RXADD to the row decoder responsive to an auto-refresh signal AREF or a self-refresh signal SREF in order to perform a refresh operation. Responsive to the refresh address(es) RXADD, the row decoder 208 refreshes the memory cells along one or more word lines associated with RXADD as part of the refresh operation. In this manner, information may be maintained in the memory cells of the array 218.

There may be one or more modes of the device 200 that include receiving refresh commands from a controller. For example, when the device 200 is in an active mode and is available for access operations, the controller may decide when refresh operations should be performed by providing refresh commands. These modes will generally be referred to as auto-refresh modes. When the refresh command is received, the command decoder 206 generates an auto-refresh signal AREF and provides it to the refresh control circuit 240. There may be one or more modes of the device 200 that include performing self-refresh operations based on internal timing. For example, when the device is in a low power state such as a standby state or a sleep mode, device may perform self-refresh operations with internal timing to preserve information. These modes will generally be referred to as self-refresh modes. During a self-refresh mode, the device 200 generates a self-refresh signal SREF, for example with periodic timing based on an oscillator circuit. The self-refresh signal SREF may be a periodic signal which begins toggling when the device 200 is in a self-refresh mode and stops toggling when the device 200 exits the self-refresh mode. Responsive to SREF, the refresh control circuit 240 performs one or more refresh operations. The memory may receive a self-refresh entry command from the controller and enter a self-refresh mode and begin generating SREF, and then receive a self-refresh exit command from the controller and exit the self-refresh mode.

The device 200 includes an array of resistive storage elements (e.g., 134 of FIG. 1) for example a fuse array. The array of resistive storage elements includes resistive elements which may be used as non-volatile storage. For example, the array 232 may include resistive elements such as fuses, antifuses, or combinations thereof. The array 232 may be used to store information about the device 200, settings of the device 200, calibrations of the device 200, operational modes of the device 200, identification information about the device 200, telemetry information about the device 200 as described in more detail herein, or combinations thereof. The array 232 may be arranged into different sets of resistive elements, and the state of the resistive elements may be used to encode information. Some sets may encode information in a binary fashion, for example based on whether a fuse/antifuse is blown or not. Some sets may encode information based on a resistance of the resistive element. Some sets may encode information based on a mixture of which fuses/antifuses are blown and the resistance of other fuses/antifuses.

The device 200 includes a telemetry logging circuit 216. The telemetry logging circuit adjusts the resistance of one or more resistive elements in the array 232 based on telemetry information. The telemetry information may be based on received commands, addresses, mode signals, or combinations thereof. For example, the telemetry logging circuit 216 receives one or more of the read signal R, the write signal W, the row address XADD, the column address YADD, and the bank address BADD. The telemetry logging circuit 216 may also receive mode signals such as AREF which indicates an auto-refresh mode or SREF which indicates a self-refresh mode. Responsive to one or more of those signals, the logging circuit selects one or more sets of resistive elements in the array 232 to adjust. The logging circuit 216 applies a voltage to one or more of the resistive elements in the selected set(s) of resistive elements. The applied voltage may be enough to permanently change the resistance of the one or more resistive elements but less than a threshold voltage at which the element would become blown. In some embodiments, the voltage may be applied once each time the signal is received by the logging circuit 216. In some embodiments, the voltage may be applied while the signal is active. In some embodiments, a clock signal may be used to determine when to apply the voltage while the signal is active, for example, at each rising edge of the clock signal LCLK while the signal is active. In some embodiments, combinations of these techniques may be used on different resistive elements of the array 232 or on a same resistive element 232. In some embodiments the voltage may be applied to multiple resistive elements to store the information in a redundant fashion.

An example implementation is described with respect to antifuses, however other forms of resistive elements may be used in other example embodiments. A set of one or more telemetry antifuses in the array 232 may be used to encode information related to a piece of telemetry. For example, a read telemetry antifuse in the array 232 may be used to track a number of received read commands. When the logging circuit 216 receives the signal R, it applies a voltage to the read telemetry antifuse. The voltage may be selected such that it adjusts the resistance of the antifuse, for example to decrease the resistance, without blowing the antifuse and causing it to become a conductive element. By determining a change in the resistance in the read telemetry antifuse, information about the quantity of read commands the device has received may be extracted. In some embodiments, multiple antifuses may be set aside for a single piece of information. If one antifuse reaches a maximum value (e.g., by being blown), the logging circuit may move on to adjust a next antifuse in the set. In this way the number may be encoded by the number of blown antifuses in the set and a resistance of one of the antifuses in the set. Other pieces of information may be encoded in analogous fashion.

In another example piece of telemetry information, the telemetry logging circuit 216 may track information related to a distribution of received row addresses XADD. The row address may be a multi-bit value. The array 232 includes a set of row address telemetry antifuses with the set including a quantity of antifuses matching the quantity of row address bits. When the telemetry logging circuit 216 receives a row address, it changes the resistance of the row address telemetry antifuses which correspond to bits of the row address which are active (e.g., at a logical high). For example, if the first bit of the row address is a logical high, a first row address telemetry antifuse will be changed, if the second bit of the row address is a logical low, a second row address telemetry antifuse will not be changed. In this manner, the resistances of the row address telemetry antifuses may track a distribution of the value of row addresses. This in turn may indicate a distribution of where information is being stored in the memory cell array 218.

The device 200 includes a mode register 230. The mode register includes one or more storage elements, such as latch circuits, organized in registers. The registers store information such as settings of the memory, information about the memory, or combinations thereof. A controller (e.g., 150 of FIG. 1) may perform a mode register read operation to retrieve information from a specified register or a mode register write operation to write information to a specified register. Some registers may be read only to prevent the controller from modifying them. Some registers may be updated based on conditions or operations of the memory. For example, a refresh rate multiplier register may be set based on a measured temperature of the array 218.

The device 200 may include an optional readout circuit 234 (e.g., 136). The readout circuit determine the resistance of one or more of the resistive elements in the array 232. For example, the readout circuit 234 may apply a known current a measure a voltage drop across the resistive element, apply a known voltage and measure the current through a resistive element, or combinations thereof. In some embodiments, the readout circuit 234 may determine a change in resistance. For example, the readout circuit 234 may compare a current resistance against a nominal resistance or against a resistance measured before the telemetry logging began. For example, the resistance of the telemetry antifuses may be measured in a factory environment before the device 200 is shipped. Those measured resistances may be stored on the device 200 for example in non-volatile storage such as the fuse array 232, off the device for example in records related to the device's serial number, or combinations thereof.

In some embodiments, the optional readout circuit 234 may generate a value based on the resistance values of the telemetry resistive elements and write those values to one or more registers of the mode register 230. In some embodiments, the readout circuit 234 may generate a value which directly reflects a measured resistance of one or more resistive elements. In some embodiments, the readout circuit 234 may generate a value derived from the measured resistance, such as a value which reflects a range bin that the measured resistance is in.

The power supply terminals are supplied with power supply potentials VDD and VSS. The power supply potentials VDD and VSS are supplied to an internal voltage generator circuit 224. The internal voltage generator circuit 224 generates various internal potentials VARY, and the like based on the power supply potentials VDD and VSS supplied to the power supply terminals.

The power supply terminals are also supplied with power supply potentials VDDQ and VSSQ. The power supply potentials VDDQ and VSSQ are supplied to the input/output circuit 222. The power supply potentials VDDQ and VSSQ supplied to the power supply terminals may be the same potentials as the power supply potentials VDD and VSS supplied to the power supply terminals in an embodiment of the disclosure. The power supply potentials VDDQ and VSSQ supplied to the power supply terminals may be different potentials from the power supply potentials VDD and VSS supplied to the power supply terminals in another embodiment of the disclosure. The power supply potentials VDDQ and VSSQ supplied to the power supply terminals are used for the input/output circuit 122 so that power supply noise generated by the input/output circuit 122 does not propagate to the other circuit blocks.

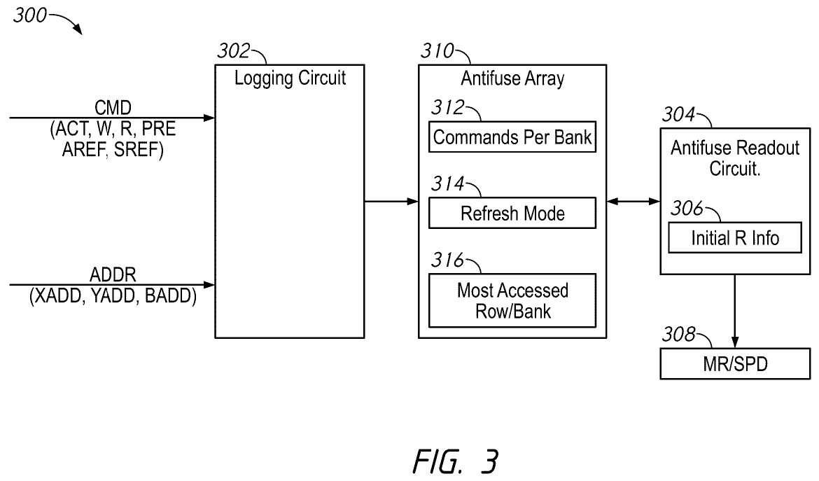

FIG. 3 is a block diagram of a telemetry logging logic according to some embodiments of the present disclosure. The telemetry logging logic 300 may, in some embodiments, implement a portion of a memory device, such as 104 of FIG. 1, 200 of FIG. 2, or combinations thereof. The logging logic 300 represents an example of certain components useful for telemetry logging. FIG. 3 is described with respect to an example implementation with three example pieces of telemetry information, commands per bank telemetry 312, refresh mode telemetry 314, and most accessed row/bank telemetry 316. Other example embodiments may include more or fewer pieces of telemetry information, which may include information which is the same or different than the example telemetry information 312-316 described herein. For example, any subset of the three pieces of information 312-316 may be used, such as any one of 312-316, any two of 312-316, or all three of 312-316.

The telemetry logging logic 300 includes a telemetry logging circuit 302 (e.g., 132 of FIG. 1, 216 of FIG. 2, or combinations thereof), an antifuse array (e.g., which may implement the resistive element array 134 of FIG. 1, the fuse array 232 of FIG. 2, or combinations thereof), and antifuse readout circuit 304 (e.g., 136 of FIG. 1, 234 of FIG. 2, or combinations thereof), and storage 308 such as a mode register (e.g., 230 of FIG. 2), an SPD (e.g., 114 of FIG. 1) or combinations thereof. The telemetry logging circuit 302 receives one or more command and/or mode signals CMD, one or more addresses ADDR, or combinations thereof and uses that information to determine when to apply a voltage to a resistive element of the array 310, and which resistive element to apply the voltage to. The readout circuit 304 measures the resistance of one or more resistive elements in the array 310 to determine the telemetry information stored therein, and writes values determines therefrom to the storage 308. The readout circuit 304 and storage 308 may be optional, and may be omitted (or not used) in some embodiments.

The embodiment of FIG. 3 is described with respect to three example pieces of telemetry which may be logged, the commands per bank telemetry 312, the refresh mode telemetry 314, and the most accessed row/bank telemetry 316. The commands per bank telemetry 312 measures the number of certain commands which are received by a bank. The commands per bank telemetry 312 may be repeated on a bank by bank basis. For example, there may be a first commands per bank telemetry 312 for a first bank, a second commands per bank telemetry 312 for a second bank, and so forth. During an access operation, the telemetry logging circuit 302 receives command signals such as ACT, W, R, PRE, or combinations thereof, as well as a bank address BADD. Based on the bank address BADD, the telemetry logging circuit 302 selects a set of antifuses in the array 310 used to store the commands per bank telemetry 312 associated with the bank specified by BADD. Any time ACT, W, R, or PRE is received, the telemetry logging circuit 302 applies a voltage to change the resistance of the selected set of antifuses. In this manner, the set of antifuses for the commands per bank telemetry 312 may have a resistance which reflects the number of times that ACT, W, R, or PRE is provided to that bank.

In some embodiments, the different commands may be logged separately. For example, for each bank there may be a first antifuse which logs how many times ACT is received, a second antifuse which logs how many times W is received, a third antifuse which logs how many times R is received and a fourth antifuse which logs how many times PRE is received. In some embodiments, two or more of the commands may have combined logging. For example, a same antifuse may have its resistance changed responsive to either ACT or PRE.

The refresh mode telemetry 314 logs information related to auto-refresh and self-refresh modes. For example, the refresh mode telemetry 314 may log AREF commands received on a bank by bank basis. For example a first antifuse may log how many times AREF was received by a first bank, a second antifuse may log how many times AREF was received by a second bank and so forth. Similar to the commands per bank telemetry 312, when an auto-refresh command provided by the command decoder (e.g., responsive to a refresh command received by the memory) a bank address BADD is provided by the address decoder. The logging circuit 302 uses the bank address BADD to determine which refresh mode telemetry 314 to change. In addition to logging AREF frequency per bank, the refresh mode telemetry 314 may log information about a self-refresh mode. For example, the logging circuit 302 may receive the self-refresh oscillator signal SREF, and may change an antifuse used for SREF logging for each pulse of the self-refresh oscillator signal SREF. Since the self-refresh oscillator signal is only toggling during a SREF mode, the resistance on the SREF antifuse may indicate an amount of time the device has spent in a SREF mode. In some embodiments, the SREF logging may be repeated on a bank by bank basis similar to the AREF logging.

The most accessed telemetry 310 may be used to log information about the most accessed row, the most accessed column, the most accessed bank, or combinations thereof. In some embodiments, the most accessed telemetry 316 may include an antifuse for each element to be tracked. For example, a first antifuse may represent a first bank, a second antifuse may represent a second bank, and so on. In another example, a first antifuse may represent a first address (or range of addresses), a second antifuse may represent a second address (or range of addresses) and so on. When the logging circuit 302 receives a command associated with an access operation such as ACT, it may change the resistance of an antifuse selected based on one or more of the of bank address BADD, column address YADD, and row address XADD. In another example implementation, the most accessed telemetry 316 may include an antifuse for each bit of an address. For example if the row address is 17 bits, then there may be 17 antifuses used for tracking the most accessed row. When an address is received, the logging circuit 302 changes the resistance of each antifuse corresponding to a bit of the address which is a logical high. In this way the resistances of the antifuses may represent a distribution of the bits of the addresses.

The antifuse readout circuit 304 measures the resistance of one or more of the antifuses in the array 310 in order to determine the information stored therein. The antifuse readout circuit 304 may measure the resistances of the one or more antifuses which make up one or more of the telemetries 312-316 and determine a value based on the measured resistance. The antifuse readout circuit 304 may write the value to the storage 308. For example, the value may be written to one or more registers of the mode register, to the SPD of the module, or combinations thereof. In some embodiments, the antifuse readout circuit 304 may read the information based on a command, periodically, or combinations thereof.

In some embodiments, the antifuse readout circuit 304 may use initial resistance information 306 to determine the value. For example, at an initial time (e.g., in a factory setting) before any of the resistive elements have been changed, the resistance of one or more resistive elements may be measured. This may determine a ‘time 0’ characteristic of the resistive elements. The time 0 characteristic may be stored on the memory device, for example in non-volatile storage. The antifuse readout circuit 304 may compare the current resistance value(s) read from the array 310 to the stored time 0 characteristic to determine a change in the resistance value. The value readout from the readout circuit 304 may be based on this comparison.

The telemetry information stored in the storage 308 may be accessed in order to determine information about the operation of the memory device. For example, the commands per bank 312 information may be used to help build an overall power usage model. The refresh mode telemetry 314 information may be used to determine a ‘total use time’ of the bank by comparing the number of AREFs received by one or more of the banks, indicating time the memory was in an active mode, to the number of times the memory generated SREF, indicating a length of time it was in a self-refresh mode. The most accessed row/bank telemetry 316 may be used to determine usage trends, to determine if the memory array is being evenly utilized, or combinations thereof.

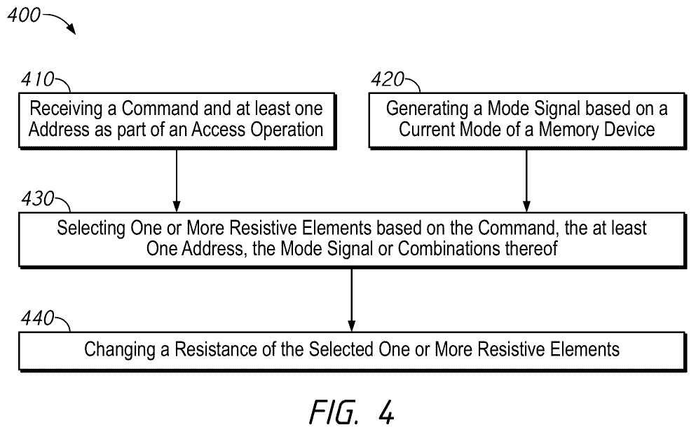

FIG. 4 is a flow chart of a method of logging telemetry information according to some embodiments of the present disclosure. The method 400 may, in some embodiments, be performed by one or more of the apparatuses or systems described herein. In some embodiments, the method 400 may be performed by a memory device such as 104 of FIG. 1 and/or 200 of FIG. 2, for example by telemetry logic such as 300 of FIG. 3.

The method 400 begins with boxes 410 and 420, which describe separate processes which may be ongoing in the memory. Box 410 describes receiving a command and at least one address as part of an access operation. For example, box 410 may include receiving a command such as an activation command ACT, a pre-charge command PRE, a read command R, a write command W, a refresh command AREF, or combinations thereof as part of the access operation. The at least one address may include one or more of a row address XADD, a column address YADD, or a bank address BADD. In some embodiments, the method 400 may include generating internal signals responsive to the received commands, address, or combinations thereof.

Box 420 describes generating a mode signal based on a current mode of a memory device. For example, box 420 may describe generating a self-refresh signal while the memory is in a self-refresh mode. For example, the method 400 may include receiving a self-refresh mode entry command and beginning to toggle a self-refresh signal responsive to entering the self-refresh mode. The method 400 may include receiving a self-refresh mode exit command and stopping toggling the self-refresh signal responsive to exiting the self-refresh mode. Other mode signals may also be used. For example, in some modes an internal signal may be generated at an active level as long as the memory device is in that mode.

Box 430 describes selecting one or more resistive elements based on the command, the at least one address, the mode signal, or combinations thereof. For example, box 430 may include selecting the one or more resistive elements in an array (e.g., 134 of FIG. 1, 232 of FIG. 2, 310 of FIG. 3, or combinations thereof) with a telemetry logging circuit (e.g., 132 of FIG. 1, 216 of FIG. 2, 302 of FIG. 3, or combinations thereof). The resistive elements may be antifuses in some embodiments. Which resistive elements are selected may be based on what telemetry is being tracked. For example, if commands per bank telemetry (e.g., 312 of FIG. 3) is being tracked, then the method 400 may include selecting a set of resistive elements based on the bank address, where the set of resistive elements are associated with the bank specified by the bank address. The method may include selecting one or more resistive elements within the set selected based on the bank address based on the command. For example selecting a first resistive element for a first type of command (e.g., an activation command ACT), selecting a second resistive element for a second type of command (e.g., a read command R) and so forth.

Box 430 is followed by box 440, which describes changing a resistance of the selected one or more resistive elements. For example, the method 400 may include applying a voltage, current, or combination thereof to the selected one or more resistive elements. This may change the resistance of the one or more resistive elements. The voltage and/or current may be large enough to permanently change the resistance of the resistive element, but less than a threshold amount which would cause the antifuse to become blown. For example, if the resistive element is an antifuse, the method 400 may include permanently reducing a resistance of the antifuse.

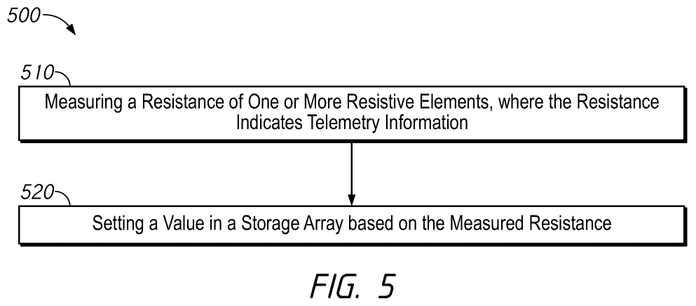

FIG. 5 is a flow chart of a method of reading telemetry information stored on a memory device according to some embodiments of the present disclosure. The method 500 may, in some embodiments, be performed by one or more of the apparatuses or systems described herein. In some embodiments, the method 400 may be performed by a memory device such as 104 of FIG. 1 and/or 200 of FIG. 2, for example by telemetry logic such as 300 of FIG. 3.

The method 500 may represent a method of reading out telemetry information from a resistive element array (e.g., 134 of FIG. 1, 232 of FIG. 2, 310 of FIG. 3, or combinations thereof) so that it may be stored in a location that is easier to access than the resistive element array, for example in storage (e.g., 308 of FIG. 3) such as a mode register (e.g., 230 of FIG. 2), module storage such as an SPD (e.g., 114 of FIG. 1), or combinations thereof.

The method 500 may generally begin with box 510 which describes measuring a resistance of one or more resistive elements, where the resistance indicates telemetry information. For example, the one or more resistive elements may have a resistance based on the telemetry logging described with respect to the method 400 of FIG. 4. For example, the telemetry information may be based on a quantity of times that one or more commands, addresses, mode signals, or combinations thereof was received. Measuring the resistance may include running a known current through the one or more resistive elements and measuring the voltage, running a known voltage across the one or more resistive elements and measuring the current or combinations thereof.

Box 510 may generally be followed by box 520, which describes setting a value in a storage array, such as a mode register, SPD, or combinations thereof, based on the measured resistance. Box 520 may include determining the value based on the measured resistance. In some embodiments, the method 500 may include setting a value which reflects the measured resistance. In some embodiments, the method 500 may include determining a value based on the measured resistance. For example, the value may reflect a range bin which includes the measured resistance. In some embodiments, the value may be based on one or more resistances. For example, the method 500 may include measuring a first resistance which represents a number of read commands on a bank, measuring a second resistance which represents a number of write commands on the bank, and then determining a value based on the ratio of the first and the second resistances.

In some embodiments, the value may be determined based on a comparison between the measured resistance and a stored initial resistance, such as a time 0 characteristic. For example, the value may be based on a difference between the measured resistance and the initial resistance. If the resistive element is an antifuse, then the value may be determined based on how much the resistance has decreased from the time 0 characteristic.

In some embodiments, the method 500 may be performed on-demand, for example responsive to a received command. In some embodiments, the method 500 may be performed periodically. In some embodiments, instead of the method 500 or in addition to the method 500, the resistances in the array may be directly read by an external device.

Of course, it is to be appreciated that any one of the examples, embodiments or processes described herein may be combined with one or more other examples, embodiments and/or processes or be separated and/or performed amongst separate devices or device portions in accordance with the present systems, devices and methods.

Finally, the above-discussion is intended to be merely illustrative of the present system and should not be construed as limiting the appended claims to any particular embodiment or group of embodiments. Thus, while the present system has been described in particular detail with reference to exemplary embodiments, it should also be appreciated that numerous modifications and alternative embodiments may be devised by those having ordinary skill in the art without departing from the broader and intended spirit and scope of the present system as set forth in the claims that follow. Accordingly, the specification and drawings are to be regarded in an illustrative manner and are not intended to limit the scope of the appended claims.

What is claimed is:

1. An apparatus comprising:
a resistive element array comprising a plurality of resistive elements; and
a telemetry logging circuit configured to receive one or more commands, addresses, mode signals, or combinations thereof, and responsive thereto select one or more of the plurality of resistive elements based on the received one or more commands, addresses, mode signals, or combinations thereof and change a resistance of the selected one or more of the plurality of resistive elements.

2. The apparatus of claim 1, wherein the telemetry logging circuit is configured to store commands per bank telemetry in the resistive element array by selecting the one or more of the plurality of resistive elements based on a bank address, and changing the resistance responsive to a row activation command, a pre-charge command, a read command, a write command or combinations thereof.

3. The apparatus of claim 1, wherein the telemetry logging circuit is configured to store refresh mode telemetry in the resistive element array by selecting the one or more of the plurality of resistive elements based on a bank address and changing the selected one or more of the plurality of resistive elements responsive to an auto-refresh command.

4. The apparatus of claim 3, wherein the telemetry logging circuit is further configured to change the resistance of a different one or more of the plurality of resistive elements responsive to a self-refresh signal.

5. The apparatus of claim 1, wherein the telemetry logging circuit is configured to store most accessed row telemetry, most accessed column telemetry, most accessed bank telemetry, or combinations thereof in the resistive element array by selecting the one or more of the plurality of resistive elements based on a row address, a bank address, or combinations thereof.

6. The apparatus of claim 1, wherein the resistive element array is a fuse array, and wherein the plurality of resistive elements include antifuses.

7. The apparatus of claim 1, further comprising a readout circuit configured to measure a resistance of one or more of the plurality of resistive elements and write a value based on the measured resistance to a mode register, an SPD, or combinations thereof.

8. The apparatus of claim 1, wherein the telemetry logging circuit is configured to change the resistance by applying a voltage to the selected one or more of the plurality of resistive elements.

9. The apparatus of claim 1, further comprising:
an address decoder configured to provide the addresses responsive to access operations; and
a command decoder configured to provide the commands responsive to the access operations.

10. A method comprising:
receiving a command and at least one address as part of an access operation;
selecting one or more resistive elements in an array of resistive elements based on the command, the at least one address, or combinations thereof; and
changing a resistance of the selected one or more resistive elements.

11. The method of claim 10, further comprising generating a mode signal based on a current mode of a memory device; and
selecting the one or more resistive elements based on the command, the at least one address, the mode signal, or combinations thereof.

12. The method of claim 10, further comprising measuring a resistance of one or more resistive elements of the array of resistive elements; and
setting a value in a storage array based on the measured resistance.

13. The method of claim 12, further comprising generating the value by comparing the measured resistance to an initial resistance.

14. The method of claim 10, further comprising changing the resistance of the selected one or more resistive elements by an amount less than blowing the resistive element.

15. The method of claim 10, further comprising logging one or more of commands per bank telemetry, refresh mode telemetry, most accessed row telemetry, most accessed bank telemetry, or combinations thereof by changing the resistance of the selected one or more resistive elements.

16. An apparatus comprising:
a resistive element array comprising at a plurality of sets of one or more antifuses;
a command decoder configured to provide a command;
an address decoder configured to provide a bank address; and
a telemetry logging circuit configured to select one of the plurality of sets of one or more antifuses based on the bank address and change a resistance of at least one of the one or more antifuses in the selected set of one or more antifuses responsive to the command.

17. The apparatus of claim 16, further comprising a readout circuit configured to measure a resistance of the one or more antifuses in at least one of the plurality of sets of one or more antifuses, determine a value based on the measured resistance, and write the value to a mode register, an SPD, or combinations thereof.

18. The apparatus of claim 16, wherein the command is a row activation command, a pre-charge command, a read command, a write command, a refresh command, or combinations thereof.

19. The apparatus of claim 16, wherein the command decoder is configured to provide the command responsive to an access operation or a refresh operation and wherein the address decoder is configured to provide the bank address responsive to the access operation or the refresh operation.

20. The apparatus of claim 16, wherein the telemetry logging circuit is configured to apply a voltage to the at least one of the one or more antifuses in the selected set of one or more antifuses which is less than a threshold voltage of the antifuse.
